(19) United States
(12) Patent Application Publication
(10) Pub. No.: US 2026/0266872 A1
(43) Pub. Date: Sep. 10, 2026

(54) TEST APPARATUS HAVING PROBE CARD WITH OPTICAL TEST ELEMENTS AND RELATED METHODS

(71) Applicant: Taiwan Semiconductor Manufacturing Company Limited, Hsin-Chu (TW)

(72) Inventors: Chiu-Yu TSENG, Hsinchu City (TW); Cheng-Chung CHIU, Hsin-Chu (TW); Guang-Sing HUANG, Hsinchu County (TW); Kai-Yi TANG, New Taipei City (TW)

(21) Appl. No.: 19/069,372

(22) Filed: Mar. 4, 2025

(51) Int. Cl. G01R 1/073; G01R 31/311

(52) U.S. Cl. CPC G01R 1/07342; G01R 31/311

(57) ABSTRACT

A method is provided. The method includes: extending a probe of a probe card assembly to contact an electrical bump of an integrated circuit (IC) die, the IC die including a silicon photonic element thereon; extending an optical fiber of the probe card assembly to contact the silicon photonic element; and performing an electrooptical test on the IC die by a test head in electrical communication with the probe card assembly, including: transmitting a first test signal from the test head to the electrical bump via the probe, the first test signal being an electrical test signal; transmitting a second test signal via the probe card assembly to the silicon photonic element, the second test signal being an optical test signal.

### BACKGROUND

Semiconductor devices are formed on, in, and/or from semiconductor wafers, and are used in a multitude of electronic devices, such as mobile phones, laptops, desktops, tablets, watches, gaming systems, and various other industrial, commercial, and consumer electronics. One or more semiconductor fabrication processes are performed to form semiconductor devices on, in, and/or from a semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a diagrammatic view of a wafer test system, in accordance with some embodiments.

FIG. 2A illustrates a partial diagrammatic view of a wafer test system, in accordance with some embodiments.

FIG. 2B illustrates a partial diagrammatic view of a wafer test system, in accordance with some embodiments.

FIG. 2C illustrates a partial diagrammatic view of a wafer test system, in accordance with some embodiments.

FIG. 2D illustrates a partial diagrammatic view of a wafer test system, in accordance with some embodiments.

FIG. 3A illustrates a diagrammatic view of an actuator, in accordance with some embodiments.

FIG. 3B illustrates a diagrammatic view of position of actuators in a lower die of a jig of a probe card assembly, in accordance with some embodiments.

FIG. 3C illustrates a diagrammatic view of position of actuators in a lower die of a jig of a probe card assembly, in accordance with some embodiments.

FIG. 3D illustrates a diagrammatic view of position of actuators in a lower die of a jig of a probe card assembly, in accordance with some embodiments.

FIG. 4 is a flow diagram illustrating a method, in accordance with some embodiments.

FIG. 5 is a flow diagram illustrating a method, in accordance with some embodiments.

FIG. 6 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to other element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

With progress in advanced semiconductor process nodes, supercomputers, data centers, and artificial intelligence are on the rise, resulting in increased performance in high-speed computing and rapid data transmission. Silicon photonics, in which optical waveguide components that process optical signals are integrated onto silicon chips, allow integrated circuit (IC) chips or dies to handle electrical signal processing and high-speed data transmission using optical signals simultaneously. As a result, testing of both optical and electrical signals on a wafer benefits from being performed simultaneously or in an integrated manner.

In embodiments of the disclosure, to enable and improve testing for silicon photonics, a probe card assembly is provided that includes optical propagation and alignment from probe head to wafer. In some embodiments, a probe card includes silicon photonics elements that are operable to perform optical tests. In some embodiments, a probe head is operable to perform optical coupling alignment. Including optical components in the probe card assembly for performing optical testing in coordination with the probe head improves testing efficiency for high pin counts with silicon photonics. Testing methods that test electronic and optical elements of a wafer simultaneously are performed by high throughput test equipment including the test head and probe card.

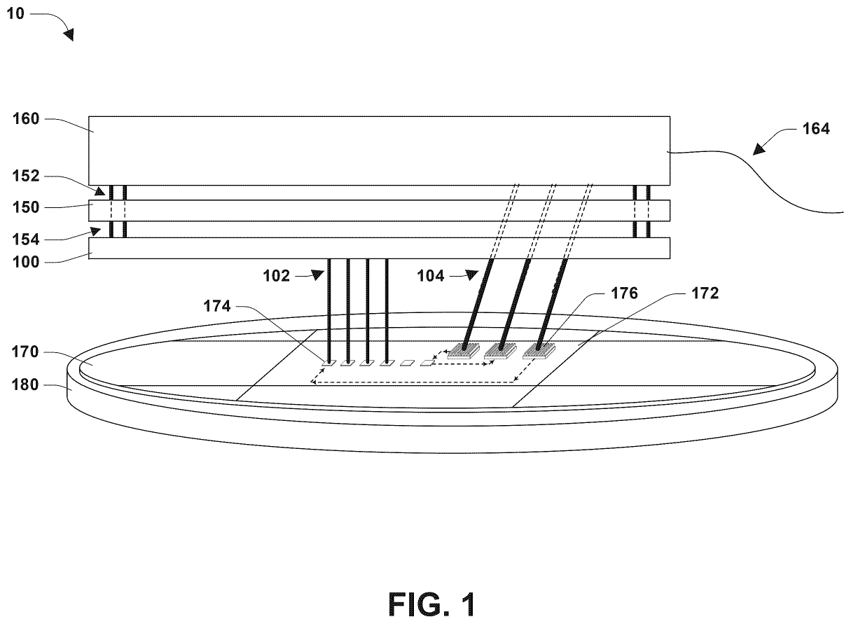

FIG. 1 illustrates a test apparatus 10 that is operable to perform electrical and optical tests on an in-process integrated circuit (IC) wafer 170, according to some embodiments.

The in-process IC wafer (or simply “the wafer”) 170 can include at least two integrated circuit die regions 172 positioned therein.

In some embodiments, a semiconductor substrate of the wafer 170 comprises at least one of a substrate, a photomask, a semiconductor device, a dielectric layer, an epitaxial layer, a silicon-on-insulator (SOI) structure, a semiconductor layer, a conductive material layer, a die, etc. The semiconductor substrate comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable material. The semiconductor substrate comprises at least one of monocrystalline silicon, crystalline silicon with a <100> crystallographic orientation, crystalline silicon with a <110> crystallographic orientation, crystalline silicon with a <111> crystallographic orientation or other suitable material. Other structures and/or configurations of the semiconductor substrate are within the scope of the present disclosure.

In some embodiments, the IC die regions 172 can be in-process dies or completed dies that are to be singulated in a subsequent process operation. The IC die regions 172 can be or include microcontrollers (MCUs), microprocessors (MPUs), graphics processing units (GPUs), artificial intelligence (AI) accelerators, memory ICs, analog ICs, logic ICs, optoelectronics, power management ICs, wireless communication ICs, and the like. In some embodiments, the IC die regions 172 can include interconnect bumps or “pads” 174 that are associated with electronic circuits and grating couplers 176 that are associated with optical elements. For example, the interconnect bumps 174 can be in electrical contact with interconnect circuitry of the electronic circuits. In some embodiments, the grating couplers 176 are in optical communication with electrooptical circuits, such as a silicon waveguide, one or more photonic integrated circuit (PIC) elements (e.g., modulators, splitters/couplers, filters, detectors, or the like), and the like. In some embodiments, the IC die regions 172 are arranged in one or more rows and one or more columns. The rows extend along a first direction and are arranged along a second direction. The columns extend along the second direction and are arranged along the first direction.

In some embodiments, each of the IC die regions 172 includes one or more patterned layers of different materials that are arranged to form electronic circuits. Components of each IC die region 172 can include transistors, interconnects, capacitors, resistors, inductors and the like. The IC die region 172 can include many material layers, such as the substrate, epitaxial layers, isolation layers, gate dielectric layers, gate electrode layers, source/drain layers, contact layers, interconnect layers, dielectric layers, passivation layers and the like. Formation of the material layers can include performing one or more semiconductor processes, such as deposition, photolithography, etching, doping, planarization, and the like. Along a vertical axis that is perpendicular to the major surface of the IC die region 172, from bottom to top, the IC die region 172 can include a device region and an interconnect region on the device region. The device region can generally include the transistors and capacitors, and the interconnect region can generally include the interconnects, capacitors, inductors, resistors and the like. The transistors can be or include field effect transistors (FETs), which can include planar transistors, fin FETs (or “FinFETs”), nanostructure FETs (e.g., nanosheet FETs or the like), vertical FETs, and the like. In some embodiments, the interconnect region can include memory devices, such as phase-change random access memory (PCRAM) devices, magnetoresistive random access memory (MRAM) devices, and/or other suitable memory devices.

The wafer 170 may be positioned on a wafer stage 180 of the test apparatus 10, which can include one or more of a wafer chuck that secures and optionally heats or cools the wafer 170, one or more actuators that can translate the wafer 170 in horizontal and vertical directions and an alignment system that can include optical alignment devices (e.g., one or more cameras, microscopes or the like), stepper motors, and the like.

In some embodiments, the test apparatus 10 includes a probe card assembly 100, a test head 160 and an optional interface or “interface board” 150 between the test head 160 and the probe card assembly 100. The test head 160 can be in data communication with a test cabinet via a cable or cable bundle 164.

In operation, a signal path is present that extends from the test cabinet or “tester” to a device under test (DUT, e.g., the IC die region 172) of the wafer 170. The test cabinet or tester generates electrical signals that are used to test semiconductor devices of the IC die region 172. This can include control signals, data signals, power, ground, and the like. The electrical signals exit the test cabinet via various connectors, which can include general purpose interface bus (GPIB), universal serial bus (USB), or other suitable high-speed interfaces. The electrical signals travel through a cable(s) 164 beneficial to maintain signal integrity. In some embodiments, the cables 164 can be or include coaxial cables for high-frequency signals, ribbon cables for parallel data, multi-conductor cables for power and control signals, and the like. The electrical signals can initially enter the test head 160, which is an assembly that is positioned between the tester and the probe card assembly 100. Within the test head 160, signal conditioning circuits like amplifiers, filters, or impedance matching networks can adjust the electrical signals for selected testing recipes, to compensate for cable losses and the like. Then, the electrical signals may be transitioned to first pogo pins 152, which can be spring-loaded pins that provide a flexible electrical connection, compensating for small misalignments. In some embodiments, the interface board 150, which can be referred to as a space transformer, is located within or near the test head 160. The interface board 150 is operable to adapt pitch of connections from the test head 160 to match pitch of the probe card assembly 100, for example, via second pogo pins 154. In some embodiments, the interface board 150 fans out signals to match density and pattern of contacts of the probe card assembly, which is beneficial for managing a transition from fewer, larger contact points to many smaller, closely spaced ones. The electrical signals are then passed through the probe card assembly 100, which can include an array of probe needles or micro-spring contacts 102. Each probe needle 102 corresponds to a selected pad 174 or test point on the IC die region 172. The probe needles 102 are positioned precisely to make contact with the pads 174 on the wafer 170. The probe card assembly 100 may be operable to test one or multiple die IC regions 172 at once, depending on a testing strategy. The electrical signals from the tester are applied to the semiconductor devices via the probe needles 102. Input signals can be applied to stimulate the device under test (DUT), and output signals can carry responses from the DUT that are captured back through the same signal path to evaluate performance, functionality, or other metrics of the IC die region(s) 172.

In some embodiments, the test head 160 is operable to generate optical signals that can be transmitted to the grating couplers 176 via optical fibers 104. The test head 160 may generate the optical signals via one or more light sources positioned therein, such as one or more edge-emitting lasers (EELs), vertical-cavity surface-emitting lasers (VCSELs), tunable lasers, quantum cascade lasers (QCLs), superluminescent diodes (SLDs), integrated laser sources, fiber lasers, or the like. In some embodiments, instead of or in addition to generating the optical signals by the test head 160, one or more optical signals may be generated by the probe card assembly 100. For example, the probe card assembly 100 may generate the optical signals via one or more light sources positioned therein, such as one or more edge-emitting lasers (EELs), vertical-cavity surface-emitting lasers (VCSELs), tunable lasers, quantum cascade lasers (QCLs), superluminescent diodes (SLDs), integrated laser sources, fiber lasers, or the like.

In operation, an optical signal chain may be present from a light source (e.g., in the test head 160 or the probe card assembly 100) to a grating coupler (e.g., the grating coupler 176) in a silicon photonics IC die region 172. Generation of an optical signal can be via an EEL, a VCSEL, or an external laser if not integrated, each of which may have benefits in wavelength, power, coherence, and modulation speed. Wavelength of the optical signal may be matched to an operational wavelength of silicon photonics circuitry, such as in telecom bands like 1310 nanometers (nm), 1550 nm, or the like. Polarization of the optical signal may be selected to match a configuration of the grating coupler 176. When the light source is an external light source, such as when the light source is not integrated, light of the optical signal from, for example, a laser may first go through an optical fiber, optionally with a lensed fiber tip for mode matching. In some embodiments, free space optics with lenses may be included to direct light onto the IC die region 172. The grating coupler 176 provides vertical light injection and can diffract light from the light source (or fiber) into a waveguide on the IC die region 172. Period, duty cycle, etch depth, and cladding materials of the grating coupler 176 may be selected to couple light efficiently at a selected wavelength and polarization. In some embodiments, the grating coupler(s) 176 include either transverse electric (TE) polarization, transverse magnetic (TM) polarization, or both. After being coupled into the IC die region 172, the light can travel through a silicon waveguide, which is depicted by dashed arrows in FIG. 1. In some embodiments, a taper is positioned immediately after the grating coupler 176 to adapt a mode from the grating coupler 176 to dimensions of the waveguide, which can reduce coupling loss. The waveguide can route the light to various components within the IC die region 172, such as modulators, splitters, filters or the like. Precise alignment is beneficial for grating couplers 176 where small misalignments can lead to significant coupling losses. When transmitting data via the optical signals, the light thereof can pass through an electro-optic (EO) modulator, which is operable to modulate phase, amplitude, or polarization of the light based on an electrical signal. The EO modulator can be or include a Mach-Zehnder modulator (MZM), electro-absorption modulator (EAM), a ring resonator modulator, or the like. In embodiments in which the light exits the IC die region 172 for further testing or transmission, the light can pass through another of the grating couplers 176 to couple the light back into another of the optical fibers 104 for output. In some embodiments, additional components including one or more of optical power meters, spectrum analyzers, oscilloscopes or the like can be included in the tester to characterize the electrical and/or optical signals at different points along the electrical signal chain, the optical signal chain, or both.

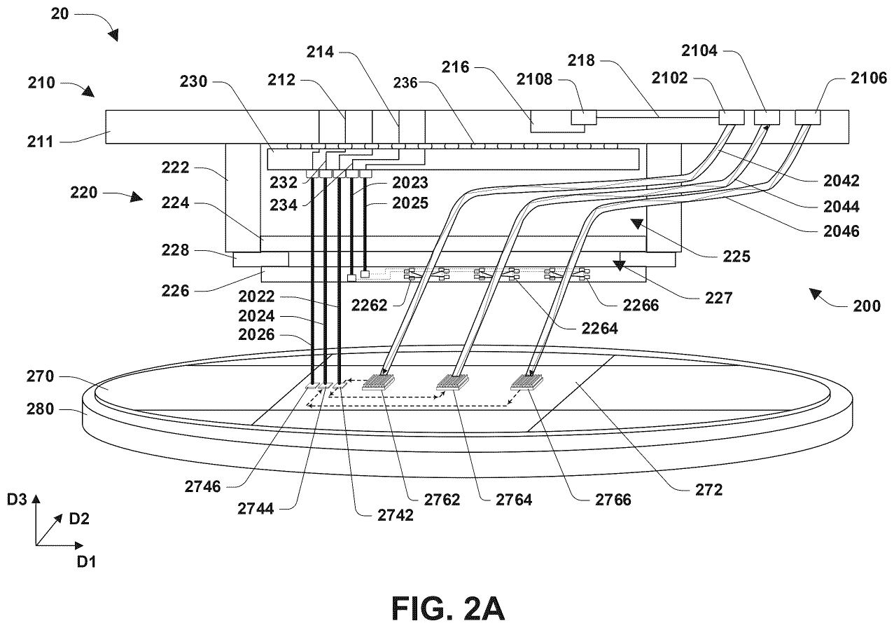

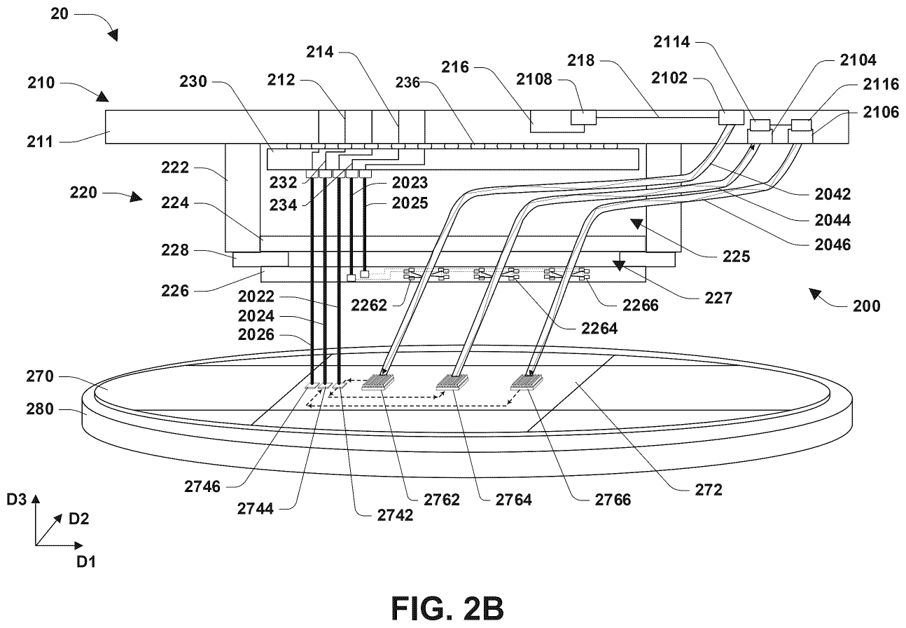

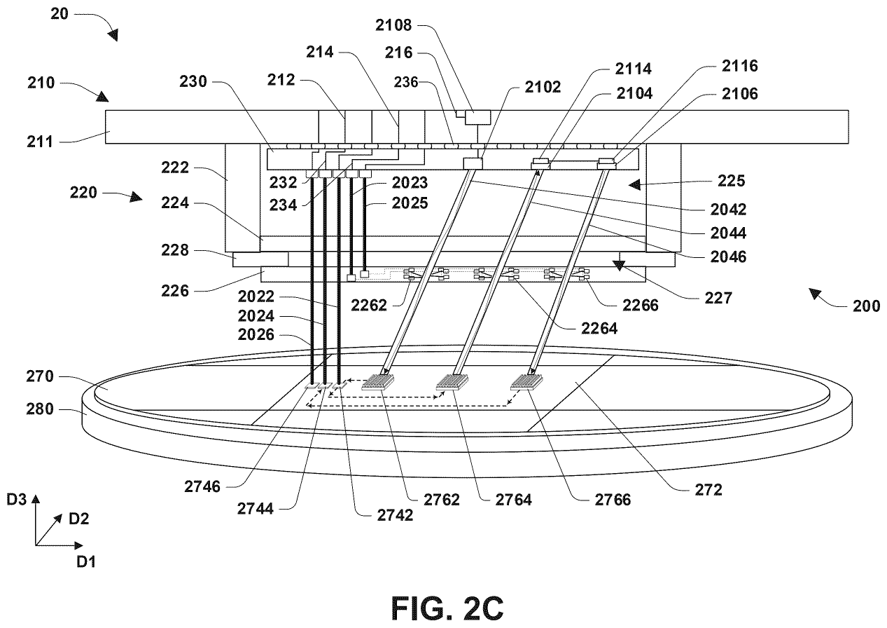

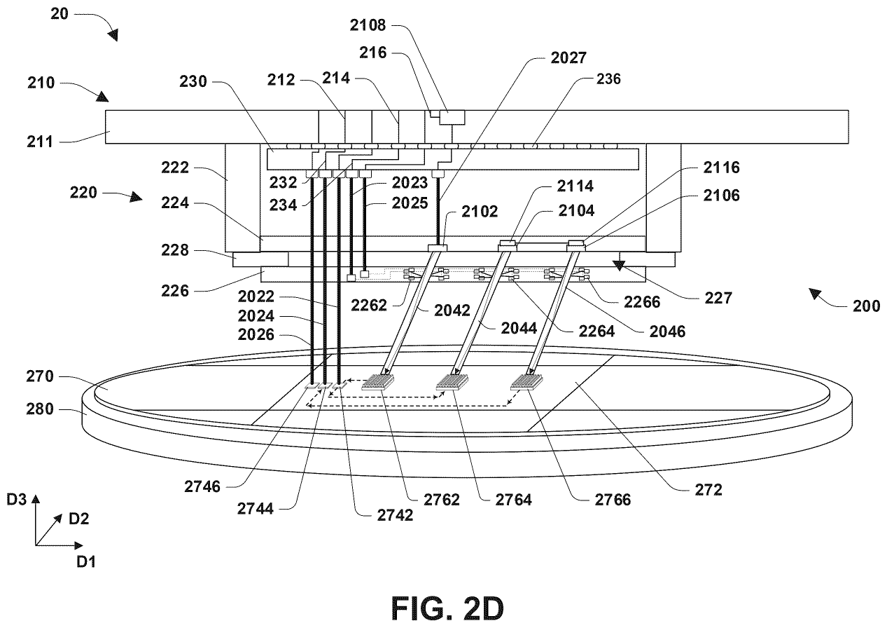

FIGS. 2A, 2B, 2C, and 2D illustrate partial diagrammatic views of a wafer test system, in accordance with some embodiments. In FIGS. 2A-2D, probe card assemblies 20 are illustrated that include a probe card 210, a jig assembly 220 on the probe card 210, and a multilayer organic (MLO) substrate 230 on the probe card 210 in a space defined by the jig assembly 220. Many elements of the wafer test systems of FIGS. 2A-2D are similar in most respects to those described with reference to FIG. 1, and can be understood in detail by referring to the description that references FIG. 1.

In FIG. 2A, a wafer 270 may be positioned on a wafer stage 280 of the wafer test system. The wafer 270 and the wafer stage 280 are similar in most respects to the wafer 170 and the wafer stage 180 described with reference to FIG. 1. Major surfaces of the wafer 270 and the IC die region 272 thereof may be oriented in a horizontal plane that includes a first direction D1 and a second direction D2 that are transverse (e.g., perpendicular) each other. A third direction D3 or “vertical direction” may be perpendicular to the horizontal plane.

The probe card assembly 20 is positioned above the wafer 270 and the wafer stage 280 in a third direction D3, and is operable to perform electrical tests, optical tests, integrated electrical-optical tests and the like on an integrated circuit (IC) die region 272 of the wafer 270. The IC die region 272 is similar in most respects to the IC die region 172 described with reference to FIG. 1. The probe card assembly 20 includes the probe card 210, the jig assembly 220, and the MLO substrate 230.

The probe card 210 includes first electronic circuits 212, second electronic circuits 214, a controller 2108, a first controller interconnect 216, a second controller interconnect 218, a light source 2102, an optical receiver channel 2104 and an optical transmitter channel 2106.

In some embodiments, the probe card 210 may include a substrate 211, which can be or include a printed circuit board (PCB) having at least two layers. The PCB can be or include a multi-layer printed circuit board that has high-density interconnects (HDI). The PCB can include materials, such as FR-4 (“Flame Retardant 4”), polyimide or BT resin, with multiple routing layers to provide complex signal paths. The PCB can include via structures for vertical interconnects, which can include micro-vias for finer pitch, and may include openings therein for mounting probe needles 2022, 2024, 2026, 2023, 2025 through drilled holes or as part of an integrated probe array.

In some embodiments, the first electronic circuits 212, the second electronic circuits 214 or both may include one or more of (i) signal routing and fanout elements, (ii) impedance matching elements, (iii) signal conditioning circuits, (iv) power distribution circuits, (v) thermal management circuits, (vi) protection circuits, and the like. The signal routing and fanout elements can include copper or other metal traces on a printed circuit board substrate 211 of the probe card 210 that distribute signals from the test head 160 to the probe needles 2022, 2024, 2026, 2023, 2025. The traces can be selected to maintain signal integrity over short distances. Fanout can involve matching wider pitch of the connections from the test head 160 to the much finer pitch of the probe needles 2022, 2024, 2026, 2023, 2025. The impedance matching elements can include the traces, which can be or include selected widths and spacings to match characteristic impedance of the test head 160 (e.g., 50 ohms for high-frequency signals) to reduce reflections. Signal conditioning circuits can include: (i) capacitors that filter out noise or provide alternating current (AC) coupling, (ii) resistors for termination, biasing, or impedance matching, (iii) inductors for filtering or impedance matching, and the like. Power distribution circuits can include power planes, such as layers or areas on a printed circuit board (PCB) of the probe card 210 for distributing power uniformly to various regions of the probe card 210. The power distribution circuits can include decoupling capacitors that are positioned near power connections to stabilize voltage and reduce noise. Thermal management circuits or elements can include thermal vias that conduct heat away from sensitive components or areas, heat spreaders that distribute heat across the probe card 210, and the like. The protection circuits can include electrostatic discharge (ESD) protection circuits, such as diodes or varistors that protect sensitive devices from static electricity. The protection circuits can include overvoltage protection that protect sensitive devices from operational overvoltages.

The first electronic circuits 212 are electrically connected to signal probe needles 2022, 2024, 2026, and the second electronic circuits 214 are electrically connected to actuator control probe needles 2023, 2025.

In some embodiments, the probe card 210 includes signal integrity components, such as a ground planes, shielding or both, which are operable to manage return paths for signals, reduce crosstalk, control electromagnetic interference (EMI), and isolate sensitive signal paths.

The controller 2108 is electrically connected to the test head 160 via the first controller interconnect 216, and is electrically connected to the light source 2102 via the second controller interconnect 218. The first controller interconnect 216 and the second controller interconnect 218 may each be or include a metal trace, such as a copper trace. The controller 2108 is operable to control light emission of the light source 2102 via the second controller interconnect 218 based on an input signal received from the test head 160 via the first controller interconnect 216. In some embodiments, the controller 2108 is operable to control emission of the light source 2102 via one or more of: (i) power supply and regulation circuits, (ii) driver circuits, (iii) timing and control circuits, and the like. The power supply and regulation circuits can include direct current (DC) to DC converters, one or more current sources, linear current regulators, switching regulators, and the like. The driver circuits can include one or more of a pulse generator, a pulse width modulator (PWM) circuit, a direct digital synthesis (DDS) circuit, a current driver circuit, a current limiting circuit, or the like. The timing and control circuits can include one or more of a microcontroller, a field-programmable gate array (FPGA), counters, timers, or other suitable timing chips beneficial to improve accuracy of a firing sequence and synchronization with other system components.

In some embodiments, the light source 2102 is or includes a laser positioned in the probe card 210. In FIG. 2A, a single light source 2102 is depicted. In some embodiments, the probe card assembly 20 includes at least two light sources 2102, each of which may be a laser. The light source 2102 is electrically connected to the controller 2108. In operation, the light source 2102 generates light (e.g., laser light) based on one or more control signals or driving signals received from the controller 2108 via the second controller interconnect 218. In some embodiments, the light is laser light that has bandwidth in a range of about 850 nm to about 1700 nm. The light is outputted to a first grating coupler 2762 from the light source 2102 via a first optical fiber 2042. In some embodiments, the first optical fiber 2042 extends from the light source 2102 in the probe card 210 to the first grating coupler 2762 on the IC die region 272.

The probe card 210 includes the optical receiver channel 2104 therein. In operation, the optical receiver channel 2104 receives second light transmitted thereto via a second optical fiber 2044 coupled to a second grating coupler 2764. The optical receiver channel 2104 is operable to transmit the second light to the test head 160. In some embodiments, the optical receiver channel 2104 can be or include one or more of: (i) optical waveguides, (ii) optical fibers, (iii) grating couplers, (iv) micro-optical elements (e.g., micro-lenses or micro-mirrors), (v) photonic wire bonds, (vi) hollow-core photonic crystal fibers or “HCFs”, (vii) integrated photonic circuits (IPCs), and the like.

The probe card 210 includes the optical transmitter channel 2106 therein. In operation, the optical transmitter channel 2106 receives third light transmitted thereto via the test head 160. The optical transmitter channel 2106 is operable to transmit the third light to a third grating coupler 2766 via a third optical fiber 2046 coupled thereto. In some embodiments, the optical transmitter channel 2106 can be or include one or more of: (i) optical waveguides, (ii) optical fibers, (iii) grating couplers, (iv) micro-optical elements (e.g., micro-lenses or micro-mirrors), (v) photonic wire bonds, (vi) hollow-core photonic crystal fibers or “HCFs”, (vii) integrated photonic circuits (IPCs), and the like.

In some embodiments, the MLO substrate 230 is bonded to the probe card 210 via a plurality of bumps 236. The MLO substrate 230 includes first fanout traces 232 and second fanout traces 234. The first fanout traces 232 and the second fanout traces 234 can be or include copper traces, or other suitable conductive (e.g., metal) traces. In some embodiments, the first fanout traces 232 are electrically connected to the first electronic circuits 212 and to first, second and third probe needles 2022, 2024, 2026 of the probe needles 2022, 2024, 2026, 2023, 2025. In some embodiments, the second fanout traces 234 are electrically connected to the second electronic circuits 214 and fourth and fifth probe needles 2023, 2025 of the probe needles 2022, 2024, 2026, 2023, 2025. Generally, interconnect density in the probe card 210 and the test head 160 exceed that of the IC die region 272. Including the MLO substrate 230 is beneficial to transition interconnect density of the probe needles 2022, 2024, 2026 that contact the IC die region 272 to interconnect density of the first electronic circuits 212 and the test head 160. The MLO substrate 230 is positioned in an opening 225 defined by the jig assembly 220. In some embodiments, the MLO substrate 230 includes at least two layers of organic materials, such as polymers that can include polyimide or BT (bismaleimide triazine) resin, sandwiched between metal layers (e.g., copper). The metal layers can number from about 2 to about 20 as is beneficial to complexity of routing selection.

In some embodiments, each of the probe needles 2022, 2024, 2026, 2023, 2025 is a single wire probe, a micro-spring probe, a micro-electromechanical systems (MEMS) probe, a multi-layered probe, or the like. Each of the probe needles 2022, 2024, 2026, 2023, 2025 can include one or more materials, such as tungsten, rhenium, palladium, copper, silver, beryllium, gold, platinum, nickel, alloys thereof, combinations thereof, or the like.

The probe needles 2022, 2024, 2026, 2023, 2025 can extend from the MLO substrate 230 into and/or through the jig assembly 220. In some embodiments, the first, second and third probe needles 2022, 2024, 2026 extend through the jig assembly 220 to contact respective bumps or pads 2742, 2744, 2746 of the IC die region 272. For example, the first probe needle 2022 contacts a first bump 2742, the second probe needle 2024 contacts a second bump 2744 and the third probe needle 2026 contacts a third bump 2746. In some embodiments, the fourth and fifth probe needles 2023, 2025 extend onto, into or through a lower die 226 of the jig assembly 220 to be electrically connected with positive voltage and negative voltage terminals of micro-actuators 2262, 2264, 2266. Generally, the probe needles 2022, 2024, 2026, 2023, 2025 are positioned in the opening 225 defined by the jig assembly 220 and extend vertically through the jig assembly 220 toward the wafer stage 280 positioned beneath the jig assembly 220.

The probe card assembly 20 includes the optical fibers 2042, 2044, 2046. In some embodiments, the optical fibers 2042, 2044, 2046 are operable to test silicon photonics integrated circuits (ICs), such as the IC die region 272 are can include single-mode fibers (SMF) that are beneficial for compatibility with small mode field diameters of silicon waveguides. The optical fibers 2042, 2044, 2046 may be operable in telecom wavelengths, such as 1310 nm or 1550 nm, and may be selected for low attenuation, high bandwidth, and ability to maintain signal integrity over short distances for lab or production testing. The optical fibers 2042, 2044, 2046 may include lensed ends or angled cleaves to improve coupling with the grating couplers 2762, 2764, 2766 of the IC die region 272, reducing insertion loss and improving alignment tolerance. In some embodiments, the optical fibers 2042, 2044, 2046 can include polarization-maintaining fibers (PMFs) that are beneficial for preserving a polarization state of the light that passes therethrough.

Each of the optical fibers 2042, 2044, 2046 may be positioned outside of the jig assembly 220. For example, as depicted in FIG. 2A, the laser 2102, the optical receiver channel 2104 and the optical transmitter channel 2106 may be positioned outside of the jig assembly 220, such that the laser 2102, the optical receiver channel 2104 and the optical transmitter channel 2106 do not overlap the opening 225 in the vertical direction (e.g., the third direction D3). As such, respective first ends of the optical fibers 2042, 2044, 2046 that extend from the laser 2102, the optical receiver channel 2104, and the optical transmitter channel 2106 do not overlap the opening 225 in the vertical direction. The optical fibers 2042, 2044, 2046 extend through the jig assembly 220. In some embodiments, the optical fibers 2042, 2044, 2046 extend through the micro-actuators 2262, 2264, 2266, which are operable to make fine adjustments to positions of second ends of the optical fibers 2042, 2044, 2046 to increase optical power (e.g., coupling efficiency or brightness) thereof due to alignment with the grating couplers 2762, 2764, 2766.

The jig assembly 220 includes a jig 222, an upper die 224 attached to the jig 222, a lower die 226 and a spacer 228 that is positioned between the upper die 224 and the lower die 226.

The jig 222 is mounted to the probe card 210 and may laterally surround the MLO substrate 230, such as on four sides thereof, which can include left, right, front and back sides thereof. Top and bottom sides of the MLO substrate 230 may not be surrounded by the jig 222 in some embodiments. In some embodiments, the jig 222 is or includes a metal material, such as stainless steel or other suitable material. The jig 222 can provide benefits, including enhancing alignment precision of the probe needles 2022, 2024, 2026, 2023, 2025, ensuring quality of contact between the probe needles 2022, 2024, 2026 and the bumps 2742, 2744, 2746, and supporting mechanical integrity of the tester. The jig 222 defines openings or holes therein through which the optical fibers 2042, 2044, 2046 extend. The optical fibers 2042, 2044, 2046 can extend through the openings in the jig 222 into the opening 225. In some embodiments, the optical fibers 2042, 2044, 2046 extend through the openings in the jig 222 along the first direction D1. In some embodiments, the openings extend along the first direction D1. In some embodiments, the openings have an angular offset relative to the first direction D1, which can increase radius of curvature along length of the optical fibers 2042, 2044, 2046.

The jig assembly 220 can include the upper die 224, which is attached to the jig 222. The upper die 224 can be a cover that extends from four sidewalls of the jig 222 to cover the MLO substrate 230 and the underlying probe card 210. The opening 225 is defined by the jig assembly 220, such as by the jig 222 and the upper die 224. In some embodiments, the upper die 224 is or includes an insulating or dielectric material that is operable to isolate the probe needles 2022, 2024, 2026, 2023, 2025 from each other physically and electrically. The upper die 224 may define openings or holes therein, which can include first holes through which the probe needles 2022, 2024, 2026 extend, second holes through which the probe needles 2023, 2025 extend, and third holes through which the optical fibers 2042, 2044, 2046 extend. In some embodiments, each of the first and second holes extend along the third direction D3 (e.g., the vertical direction) and each of the third holes may extend at an angle to the third direction D3. Extending at the angle can increase radius of curvature at bends or curves along the length of the optical fibers 2042, 2044, 2046, which can reduce signal loss, reduce signal distortion, preserve polarization, and increase mechanical reliability.

The lower die 226 is offset from the upper die 224 along the third direction D3 by the spacer 228. The lower die 226, the upper die 224, and the spacer 228 define an opening 227 through which the probe needles 2022, 2024, 2026, 2023, 2025 and the optical fibers 2042, 2044, 2046 extend. The lower die 226 includes first openings through which the probe needles 2022, 2024, 2026 extend. The lower die 226 includes second openings in which the probe needles 2023, 2025 land on pads that are electrically connected to voltage terminals of the micro-actuators 2262, 2264, 2266.

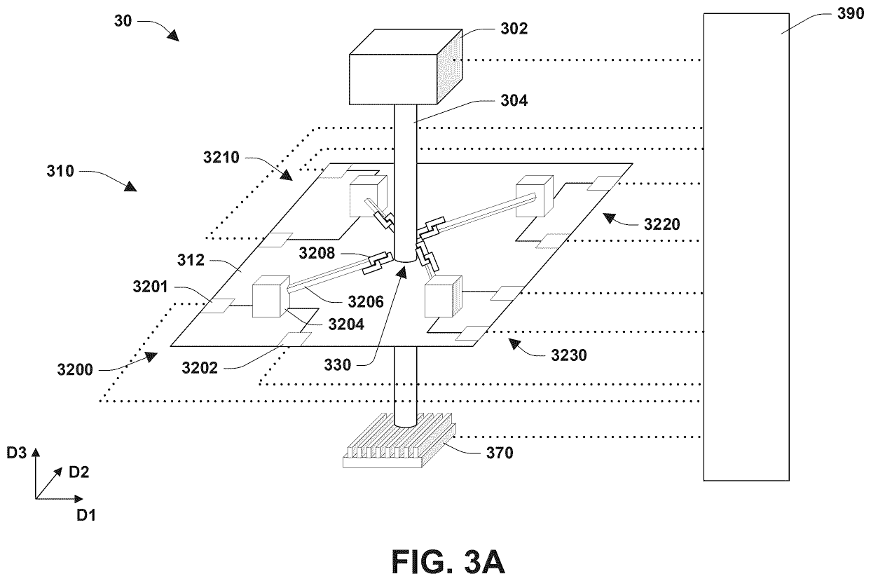

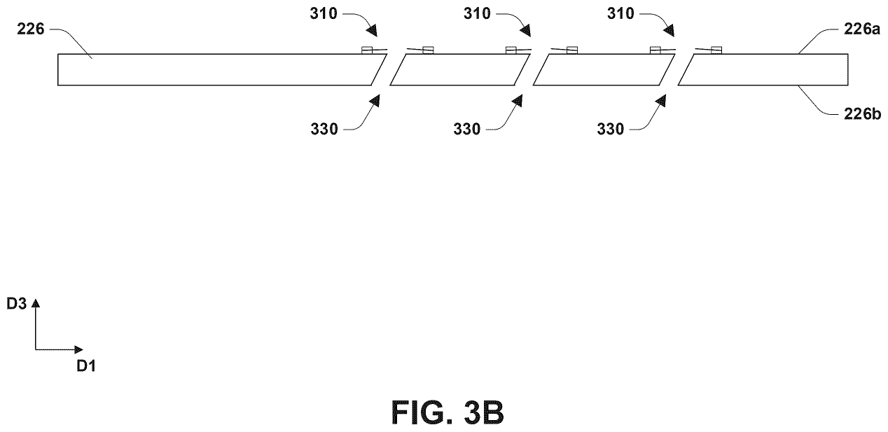

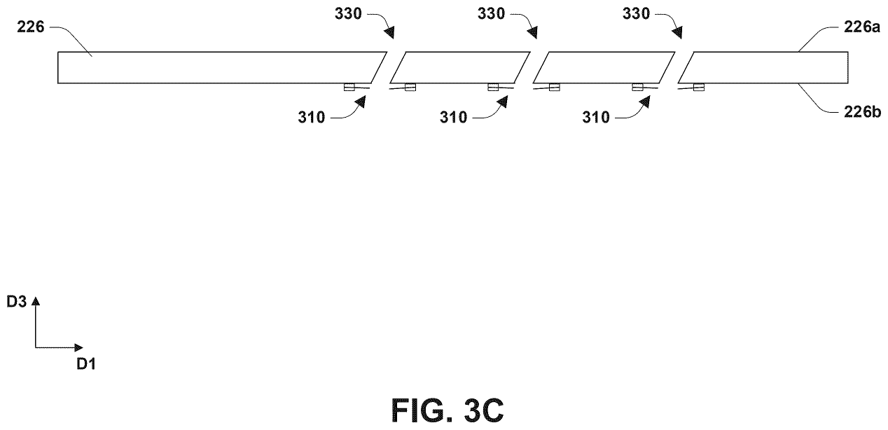

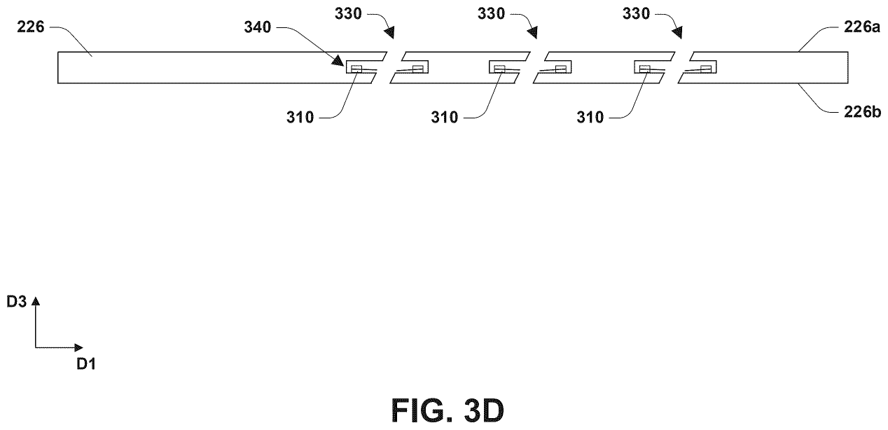

The lower die 226 includes the micro-actuators 2262, 2264, 2266. A micro-actuator 310 that is an embodiment of the micro-actuators 2262, 2264, 2266 is described in greater detail with reference to FIG. 3A. The optical fibers 2042, 2044, 2046 pass through the micro-actuators 2262, 2264, 2266, and the micro-actuators 2262, 2264, 2266 select position of the optical fibers 2042, 2044, 2046. The optical fiber 2042 passes through the micro-actuator 2262, the optical fiber 2044 passes through the micro-actuator 2264, and the optical fiber 2046 passes through the micro-actuator 2266.

The micro-actuators 2262, 2264, 2266 can be positioned on a side of the lower die 226 that faces the upper die 224, such that the micro-actuators 2262, 2264, 2266 are positioned in the opening 227 (depicted in FIG. 3B). In some embodiments, the micro-actuators 2262, 2264, 2266 are positioned on a side of the lower die 226 that faces the wafer stage 280 (depicted in FIG. 3C). In some embodiments, the micro-actuators 2262, 2264, 2266 are embedded in the lower die 226 (depicted in FIG. 3D).

The spacer 228 is positioned between the upper die 224 and the lower die 226. The spacer 228 is positioned to separate the upper die 224 from the lower die 226. In some embodiments, the spacer 228 is mounted or fastened to the jig 222.

In operation, the light source 2102 generates a first optical signal that is transmitted to the first grating coupler 2762 via the first optical fiber 2042. The first optical signal continues from the first grating coupler 2762 to a first circuit in communication with the first bump 2742. A second optical signal is generated by modulating the first optical signal based on a first electrical signal received by the first bump 2742 via the first probe needle 2022. The second optical signal travels to the second grating coupler 2764 via a waveguide (e.g., a Si waveguide, depicted by a dashed arrow), then from the second grating coupler 2764 to the optical receiver channel 2104 via the second optical fiber 2044. The test head 160 generates a third optical signal based on the second optical signal received by the optical receiver channel 2104. Then, the third optical signal travels to the third grating coupler 2766 via the optical transmitter channel 2106 and the third optical fiber 2046. The third optical signal travels from the third grating coupler 2766 to a second circuit in communication with the second bump 2744. The second circuit generates a second electrical signal that is transmitted to the test head 160 via the second probe needle 2024. Based on the first, second and third optical signals and the first and second electrical signals, the test head 160 may perform one or more tests that are electrical tests, optical tests, or both. For example, the test head 160 may perform a functional test that determines whether the IC die region 272 adequately performs selected electrical, optical, or electro-optical functions.

In some embodiments, the test head 160 selects positions of the optical fibers 2042, 2044, 2046 by the micro-actuators 2262, 2264, 2266 based on one or more of the first, second and third optical signals and the first and second electrical signals. For example, the test head 160 may determine brightness or coupling efficiency associated with each of the optical fibers 2042, 2044, 2046 to one or more of the light source 2102, the optical receiver channel 2104, the optical transmitter channel 2106, the first grating coupler 2762, the second grating coupler 2764 and the third grating coupler 2766. The test head 160 may determine whether the brightness or coupling efficiency does not exceed a threshold value. In response to the brightness or coupling efficiency not exceeding the threshold value, the test head 160 may control the respective micro-actuator 2262, 2264, or 2266 to change the position of the respective optical fiber 2042, 2044, or 2046. Then, the test head 160 may once again determine brightness or coupling efficiency associated with each of the optical fibers 2042, 2044, 2046 to one or more of the light source 2102, the optical receiver channel 2104, the optical transmitter channel 2106, the first grating coupler 2762, the second grating coupler 2764 and the third grating coupler 2766. The process operations just described may be repeated until it is determined that the brightness or coupling efficiency exceeds the threshold value. The process of selecting positions of the optical fibers 2042, 2044, 2046 by the micro-actuators 2262, 2264, 2266 via the test head 160 may be performed based on a software algorithm, such as a simulated annealing, particle swarm, genetic, gradient descent, Levenberg-Marquardt, Nelder-Mead simplex, hill climbing, combinations thereof, or the like. In some embodiments, the process described is performed by a controller of the tester that is external to the test head 160.

FIG. 2B illustrates a partial diagrammatic view of a wafer test system 20, in accordance with some embodiments. The wafer test system 20 of FIG. 2B is similar in many respects to the wafer test system 20 described with reference to FIG. 2A, and like reference numerals refer to like components.

In FIG. 2B, instead of the optical receiver channel 2104 and the optical transmitter channel 2106 communicating with the test head 160, the probe card 210 includes an optical-to-electric (OE) modulator 2114 and an electric-to-optical (EO) modulator 2116. The OE modulator 2114 is in optical communication with the optical receiver channel 2104 and in electrical communication with the EO modulator 2116. The EO modulator 2116 is in electrical communication with the OE modulator 2114 and is in optical communication with the optical transmitter channel 2106. As such, operation of the wafer test system 20 of FIG. 2B can have a shorter signal path due to inclusion of the OE modulator 2114 and the EO modulator 2116.

In operation, the light source 2102 generates a first optical signal that is transmitted to the first grating coupler 2762 via the first optical fiber 2042. The first optical signal continues from the first grating coupler 2762 to a first circuit in communication with the first bump 2742. A second optical signal is generated by modulating the first optical signal based on a first electrical signal received by the first bump 2742 via the first probe needle 2022. The second optical signal travels to the second grating coupler 2764 via a waveguide (e.g., a Si waveguide, depicted by a dashed arrow), then from the second grating coupler 2764 to the optical receiver channel 2104 via the second optical fiber 2044. The OE modulator 2114 generates a third electrical signal, then the EO modulator 2116 generates a third optical signal based on the third electrical signal received from the OE modulator 2114. Then, the third optical signal travels to the third grating coupler 2766 via the optical transmitter channel 2106 and the third optical fiber 2046. The third optical signal travels from the third grating coupler 2766 to a second circuit in communication with the second bump 2744. The second circuit generates a second electrical signal that is transmitted to the test head 160 via the second probe needle 2024. Based on the first, second and third optical signals and the first, second and third electrical signals, the test head 160 may perform one or more tests that are electrical tests, optical tests, or both. For example, the test head 160 may perform a functional test that determines whether the IC die region 272 adequately performs selected electrical, optical, or electro-optical functions. In some embodiments, the test head 160 selects positions of the optical fibers 2042, 2044, 2046 by the micro-actuators 2262, 2264, 2266 based on one or more of the first, second and third optical signals and the first, second and third electrical signals as described with reference to FIG. 2A.

FIG. 2C illustrates a partial diagrammatic view of a wafer test system 20, in accordance with some embodiments. The wafer test system 20 of FIG. 2C is similar in many respects to the wafer test systems 20 described with reference to FIGS. 2A and 2B, and like reference numerals refer to like components.

In FIG. 2C, the light source 2102, the optical receiver channel 2104, the OE modulator 2114, the optical transmitter channel 2106, and the EU modulator 2116 are positioned in the MLO substrate 230 instead of in the probe card 210. As such, operation of the wafer test system 20 of FIG. 2C can have a shorter signal path. For example, the optical fibers 2042, 2044, 2046 extend over a shorter distance from the MLO substrate 230 to the grating couplers 2762, 2764, 2766. As such, the optical fibers 2042, 2044, 2046 can be straighter over their length, having fewer curves, which can improve optical transmission efficiency and reduce noise. The openings in the jig 222 through which the optical fibers 2042, 2044, 2046 extend can be omitted. In FIG. 2C, the light source 2102, the optical receiver channel 2104, the OE modulator 2114, the optical transmitter channel 2106 and the EU modulator 2116 positioned in the MLO substrate 230 overlap the jig assembly 220, such as overlapping the lower die 226, the upper die 224, or both. Operation of the wafer test system 20 of FIG. 2C is similar in most respects to that described with reference to FIG. 2B, except that the light source 2102, the optical receiver channel 2104, the OE modulator 2114, the optical transmitter channel 2106 and the EU modulator 2116 are positioned in the MLO substrate 230.

In the embodiment depicted in FIG. 2C, the controller 2108 can be positioned in the probe card 210 and can be electrically connected to the light source 2102 via one or more of the bumps 236. In some embodiments, the controller 2108 may be positioned in the MLO substrate 230 and may be in electrical communication with the first controller interconnect 216 via one or more of the bumps 236.

FIG. 2D illustrates a partial diagrammatic view of a wafer test system 20, in accordance with some embodiments. The wafer test system 20 of FIG. 2C is similar in many respects to the wafer test systems 20 described with reference to FIGS. 2A, 2B, and 2C, and like reference numerals refer to like components.

In FIG. 2D, the light source 2102, the optical receiver channel 2104, the OE modulator 2114, the optical transmitter channel 2106, and the EU modulator 2116 are positioned in the upper die 224 instead of in the probe card 210 or the MLO substrate 230. As such, operation of the wafer test system 20 of FIG. 2D can have a shorter signal path. For example, the optical fibers 2042, 2044, 2046 extend over a shorter distance from the upper die 224 to the grating couplers 2762, 2764, 2766. As such, the optical fibers 2042, 2044, 2046 can be straighter over their length, having fewer curves, which can improve optical transmission efficiency and reduce noise. The openings in the jig 222 and the upper die 224 through which the optical fibers 2042, 2044, 2046 extend can be omitted. In FIG. 2D, the light source 2102, the optical receiver channel 2104, the OE modulator 2114, the optical transmitter channel 2106 and the EU modulator 2116 positioned in the upper die 224 overlap the jig assembly 220, such as overlapping the lower die 226, the MLO substrate 230, or both. Operation of the wafer test system 20 of FIG. 2D is similar in most respects to that described with reference to FIGS. 2B and 2C, except that the light source 2102, the optical receiver channel 2104, the OE modulator 2114, the optical transmitter channel 2106 and the EU modulator 2116 are positioned in the upper die 224.

In FIG. 2D, the controller 2108 can be positioned in the probe card 210 and can be electrically connected to the light source 2102 via one or more of the bumps 236 and via a probe needle 2027 that extends from the MLO substrate 230 to the light source 2102. In some embodiments, the controller 2108 may be positioned in the MLO substrate 230 or the upper die 224 and may be in electrical communication with the first controller interconnect 216 via one or more of the bumps 236, one or more probe needle, or both.

FIG. 3A illustrates a diagrammatic view of an actuator system 30 including an actuator 310, in accordance with some embodiments. FIGS. 3B-3D illustrate diagrammatic views of positions of actuators 310 in a lower die of a jig of a probe card assembly, in accordance with some embodiments. The actuators 310 are embodiments of the micro-actuators 2262, 2264, 2266 described with reference to FIGS. 2A-2D.

In FIG. 3A, an optical fiber 304 extends from a first optical element 302 to a second optical element 370. The optical fiber 304 is an embodiment of the optical fibers 2042, 2044, 2046. In some embodiments, the first optical element 302 is or includes one or more of a light source (e.g., the light source 2102), an optical receiver channel (e.g., the optical receiver channel 2104), an optical transmitter channel (e.g., the optical transmitter channel 2106), or the like. In some embodiments, the first optical element 302 is or includes one or more of an OE modulator (e.g., the OE modulator 2114) or an EO modulator (e.g., the EO modulator 2116). In some embodiments, the second optical element 370 is a grating coupler (e.g., one of the grating couplers 2762, 2764, 2766). Light may travel from the first optical element 302 to the second optical element 370, from the second optical element 370 to the first optical element 302, or both.

The actuator 310 is positioned along the length of the optical fiber 304 and is operable to select position of the optical fiber 304, such as position of a first end of the optical fiber 304 connected to the first optical element 302, position of a second end of the optical fiber 304 connected to the second optical element 370, or both. In some embodiments, stepping resolution of the actuator 310 is finer than about 2 micrometers (um) in the first, second and third directions D1, D2, D3 and is finer than about 1 millidegree along three angular directions. As such, alignment resolution of the optical fiber 304 by the actuator 310 may be finer than about 2 nanometers.

A controller 390 is in data communication (e.g., electrical communication) with one or more of the first optical element 302, the actuator 310, and the second optical element 370, as depicted by dotted lines in FIG. 3A. The controller 390 is operable to select position of the optical fiber 304 via the actuator 310 based on information associated with brightness or coupling efficiency, the information being generated by the first optical element 302, the second optical element 370 or both. In some embodiments, the controller 390 selects the position of the optical fiber 304 by selecting positions of arms 3206 and spring elements 3208 of the actuator 310 by applying one or more voltages to each of at least three (e.g., four) actuating elements 3200, 3210, 3220, 3230.

The actuator 310 includes a first actuating element 3200, a second actuating element 3210, a third actuating element 3220 and a fourth actuating element 3230, which can be referred to collectively as the actuating elements 3200, 3210, 3220, 3230.

Each of the actuating elements 3200, 3210, 3220, 3230 may have substantially the same structure and function. In some embodiments, one of the actuating elements 3200, 3210, 3220, 3230 may be omitted. Description is provided with reference to the first actuating element 3200. Other actuating elements 3210, 3220, 3230 may be understood based on the description provided with reference to the first actuating element 3200.

The first actuating element 3200 includes a control element 3204, an arm 3206, a spring element 3208, a first voltage pad 3201, and a second voltage pad 3202. The first actuating element 3200 is positioned on a substrate 312.

The substrate 312 defines an opening 330 through which the optical fiber 304 extends. The actuating elements 3200, 3210, 3220, 3230 are arranged at positions around the opening 330, such that the arms 3206 thereof extend toward the optical fiber 304 extending therethrough. In some embodiments, the actuating elements 3200, 3210, 3220, 3230 are arranged at uniform intervals around the opening 330, such as being offset at 90° from each other, as depicted in FIG. 3A. In some embodiments, the actuating elements 3200, 3210, 3220, 3230 are positioned at substantially the same distance from the opening 330, such that each of the spring elements 3208 extends to overlap the opening by substantially the same dimension.

In some embodiments, the control element 3204 is or includes a piezoelectric material, which is operable to have shape thereof selected by application of a voltage potential difference across the first voltage pad 3201 and the second voltage pad 3202. In some embodiments, the control element 3204 is or includes a parallel kinematic mechanism (PKM) structure, a flexure-based structure, a multi-axis piezo stage, a hybrid structure (e.g., including electrothermal, electrostatic, shape memory alloys, or the like), a MEMS-based structure, or the like. The control element 3204 can control motion of the arms 3206 and the spring elements 3208 with number of degrees of freedom (DOF) that is in a range of 3 to 6. For example, the control element 3204 can control motion of the arms 3206 and the spring elements 3208 to include the first, second and third directions D1, D2, D3 and three angular or rotational dimensions. In some embodiments, stepping resolution of each of the arms 3206 is finer than about 2 microns in each of the first, second and third directions D1, D2, D3 and finer than about 1 millidegree in each of the three angular or rotational dimensions. The control element 3204 is positioned on the substrate 312. The control element 3204 is electrically connected to the first voltage pad 3201 and the second voltage pad 3202.

The first voltage pad 3201 and the second voltage pad 3202 are positioned on the substrate 312 or integrated in the substrate 312. The first voltage pad 3201 is electrically connected to a first end of the control element 3204, and the second voltage pad 3202 is electrically connected to a second end of the control element 3204. Voltage applied to the control element 3204 can be in a range of about 0 Volts to about 15 Volts. The voltage can be generated by the tester, an external power supply, or another suitable voltage source. In some embodiments, the voltage is selected by the tester, such as by a controller 390, which may be positioned in the tester. In some embodiments, the voltage is selected by the controller 390 that is positioned in the test head 160, in the probe card assembly 100, 20, or by the controller 390 that is positioned in another suitable element of a test system. The voltage may be selected based on alignment of the optical fiber 304 to the first optical element 302, the second optical element 370, or both, such as based on brightness or coupling efficiency, as described with reference to FIG. 2A.

The arm 3206 has motion that is selected by the voltage applied to the control element 3204. The arm 3206 extends from the control element 3204 and is operable to be in contact with and apply force to the optical fiber 304 via the spring element 3208 connected or mounted thereto. The arm 3206 extends from the control element 3204 on a first end and has the spring element 3208 positioned on a second end thereof. The arm 3206 can have length that is in a range of about 100 microns to about 1 millimeter, width that is in a range of about 5 microns to about 100 microns, and thickness that is in a range of about 500 nanometers to about 10 microns. In some embodiments, the arm 3206 is or includes one or more materials, such as silicon, silicon nitride, one or more polymers, one or more piezoelectric materials (e.g., lead zirconate titanate, zinc oxide, or the like), a metal (e.g., gold, aluminum, platinum, or the like), combinations thereof, or the like.

The spring element 3208 is positioned at the second end of the arm 3206 that is proximal the opening 330. In some embodiments, the spring element 3208 is or includes a serpentine spring. The serpentine spring can include one or more connected, S-shaped or zigzag bends that are arranged in a pattern in which each bend is substantially perpendicular to the direction of force application. In some embodiments, width and thickness of the spring element 3208 can be similar to those of the arm 3206, such as the same, slightly smaller or slightly larger. In some embodiments, the spring element 3208 includes one or more materials, which can be the same material as the arm 3206, such as silicon, silicon nitride, a metal, one or more polymers, one or more piezoelectric materials, combinations thereof, or the like. In operation, the spring element 3208 improves gentleness of contact with the optical fiber 304, for example, by distributing force evenly across the spring, which can reduce stress concentration and prevent material fatigue.

FIG. 3B illustrates a view of the lower die 226 of the jig assembly 220 that has at least three of the actuators 310 positioned thereon, in accordance with some embodiments. In some embodiments, the lower die 226 includes an upper surface 226a that faces the upper die 224 and a lower surface 226b that faces the wafer stage 280. In some embodiments, one or more of the actuators 310 is positioned on the upper surface 226a of the lower die 226, such that the actuators 310 are positioned in the opening 225 between the upper die 224 and the lower die 226. In some embodiments, the lower die 226 is the substrate 312, and the openings 330 extend through the lower die 226. In some embodiments, the openings 330 extend through the lower die 226 at an angle relative to the vertical direction (e.g., the third direction D3). In some embodiments, the angle of taper of the openings 330 with the third direction D3 is in a range of about 0 degrees to about 45 degrees. In some embodiments, the substrate 312 of each of the actuators 310 is different than the lower die 226, and the actuators 310 are mounted to the upper surface 226a having the openings 330 that are aligned with separate openings of the lower die 226. First separation between the actuators 310 along the first direction D1 may be associated with second separation between the grating couplers 2762, 2764, 2766. For example, the first separation may be substantially the same as the second separation. In another example, the first separation may be somewhat larger than the second separation. It should be understood that, in addition to or instead of being arranged along the first direction D1, additional or the same actuators 310 may be arranged along the second direction D2.

FIG. 3C illustrates a view of the lower die 226 of the jig assembly 220 that has the at least three actuators 310 positioned thereon, in accordance with some embodiments. In some embodiments, as depicted in FIG. 3C, the actuators 310 are positioned on the lower surface 226b instead of on the upper surface 226a.

FIG. 3D illustrates a view of the lower die 226 of the jig assembly 220 that has the at least three actuators 310 positioned therein, in accordance with some embodiments. In some embodiments, the actuators 310 are embedded in the lower die 226. In some embodiments, the actuators 310 are embedded about midway between the upper surface 226a and the lower surface 226b, although other positions are also contemplated as embodiments herein. The lower die 226 may define openings 340 therein in which the actuators 310 are positioned. The openings 340 can provide sufficient space or room for the arms 3206 of the actuators 310 to translate along the first direction D1, the second direction D2 and the third direction D3.

The embodiments depicted in FIGS. 3B-3D may be combined. For example, one or more of the actuators 310 may be positioned on the upper surface 226a, one or more of the actuators 310 may be positioned on the lower surface 226b one or more of the actuators 310 may be positioned in the openings 340, or a combination thereof. In some embodiments, two or more actuators 310 may be associated with each opening 330, namely, with each optical fiber that extends through each opening. For example, a first actuator 310 may be positioned on the upper surface 226a aligned with an opening of the upper die 226, and a second actuator 310 may be positioned on the lower surface 226b aligned with the opening of the upper die 226. In this way, two of the actuators 310 may be used to select alignment of the optical fiber extended therethrough with the first optical element 302, the second optical element 370, or both.

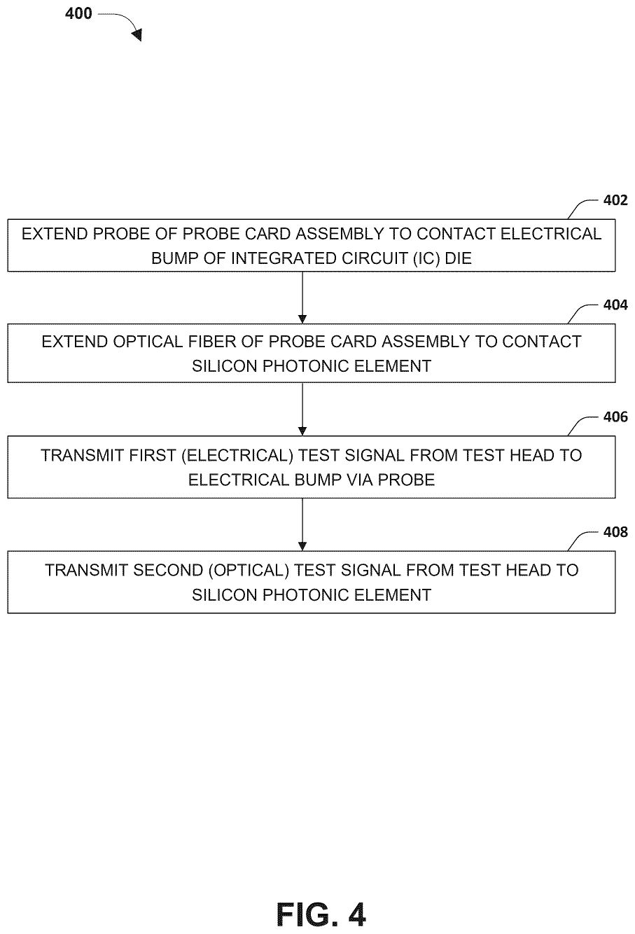

A method 400 is illustrated in FIG. 4 in accordance with some embodiments.

At 402, the method 400 includes extending a probe of a probe card assembly to contact an electrical bump of an integrated circuit (IC) die, the IC die including a silicon photonic element thereon.

At 404, the method 400 includes extending an optical fiber of the probe card assembly to contact the silicon photonic element.

At 406 and 408, the method 400 includes performing an electrooptical test on the IC die by a test head in electrical communication with the probe card assembly. At 406, the method 400 includes transmitting a first test signal from the test head to the electrical bump via the probe, the first test signal being an electrical test signal. At 408, the method 400 includes transmitting a second test signal via the probe card assembly to the silicon photonic element, the second test signal being an optical test signal.

In some embodiments, transmitting the second test signal includes: transmitting the optical test signal from the test head via an optical transmitter positioned in a probe card of the probe card assembly.

In some embodiments, transmitting the second test signal includes: generating the optical test signal by an electric-to-optical modulator based on an electrical signal, the electric-to-optical modulator being positioned in a probe card of the probe card assembly; and transmitting the optical signal from the electric-to-optical modulator via an optical transmitter positioned in the probe card.

In some embodiments, transmitting the second test signal includes: generating the optical test signal by an electric-to-optical modulator based on an electrical signal, the electric-to-optical modulator being positioned in a multilayer organic (MLO) substrate bonded to a probe card of the probe card assembly; and transmitting the optical signal from the electric-to-optical modulator via an optical transmitter positioned in the MLO substrate.

In some embodiments, transmitting the second test signal includes: generating the optical test signal by an electric-to-optical modulator based on an electrical signal, the electric-to-optical modulator being positioned in a jig assembly mounted to a probe card of the probe card assembly; and transmitting the optical signal from the electric-to-optical modulator via an optical transmitter positioned in the jig assembly.

In some embodiments, transmitting the second test signal includes: transmitting the optical test signal from the test head via a laser positioned in a probe card of the probe card assembly.

In some embodiments, transmitting the second test signal includes: transmitting the optical test signal from the test head via a laser positioned in a multilayer organic (MLO) substrate bonded to a probe card of the probe card assembly.

In some embodiments, transmitting the second test signal includes: transmitting the optical test signal from the test head via a laser positioned in a jig assembly mounted to a probe card of the probe card assembly.

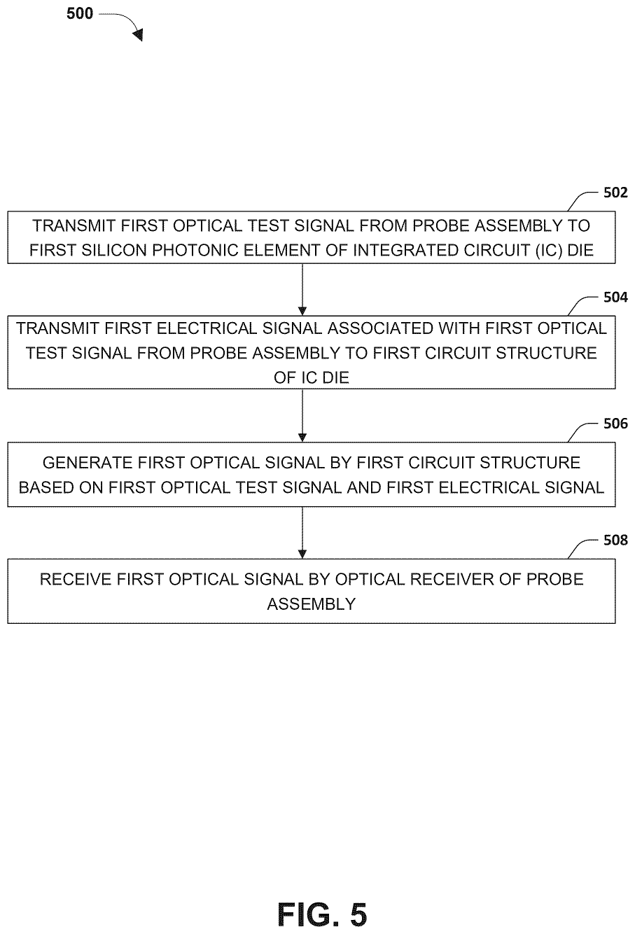

A method 500 is illustrated in FIG. 5 in accordance with some embodiments.

At 502, the method 500 includes transmitting a first optical test signal from a probe assembly to a first silicon photonic element of an integrated circuit (IC) die.

At 504, the method 500 includes transmitting a first electrical signal associated with the first optical test signal from the probe assembly to a first circuit structure of the IC die.

At 506, the method 500 includes generating a first optical signal by the first circuit structure based on the first optical test signal and the first electrical signal.

At 508, the method 500 includes receiving the first optical signal by an optical receiver of the probe assembly.

In some embodiments, the method 500 includes: generating a second optical signal associated with the first optical signal; receiving the second optical signal by a third silicon photonic element; generating a third electrical signal associated with the second optical signal by a second circuit structure of the IC die; and receiving the third electrical signal by the probe assembly.

In some embodiments, transmitting the first optical test signal includes transmitting the first optical test signal via a first optical fiber. In some embodiments, receiving the first optical signal includes receiving the first optical signal via a second optical fiber. In some embodiments, receiving the second optical signal includes receiving the second optical signal via a third optical fiber.

In some embodiments, transmitting the first optical test signal via the first optical fiber includes transmitting the first optical test signal via the first optical fiber that extends through a lower die of a jig assembly mounted to a probe card of the probe assembly.

In some embodiments, the method includes: determining optical power associated with alignment of the first optical fiber with the first silicon photonic element; and increasing the optical power by a micro-electromechanical system (MEMS) positioned in the lower die of the jig assembly.

In some embodiments, transmitting the first optical test signal via the first optical fiber includes transmitting the first optical test signal via the first optical fiber that extends through an upper die of the jig assembly that is offset from the lower die by a spacer.

In some embodiments, transmitting the first optical test signal via the first optical fiber includes transmitting the first optical test signal via the first optical fiber that extends through a jig of the jig assembly to which the spacer, the upper die and the lower die are mounted.

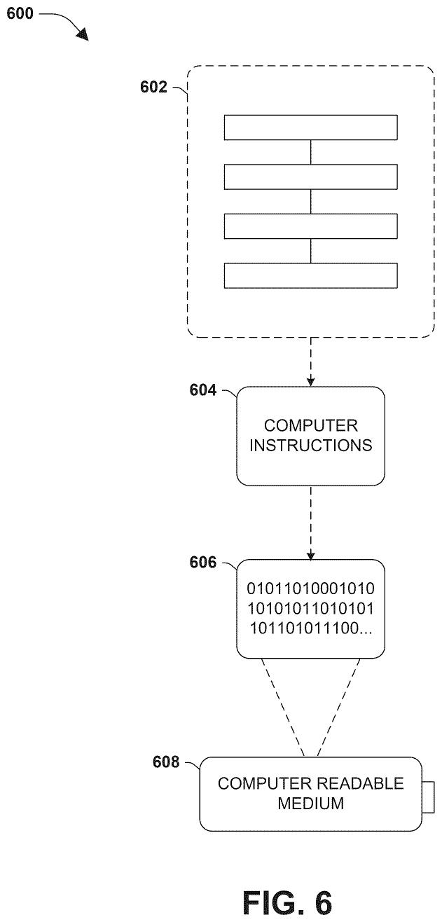

One or more embodiments involve a computer-readable medium comprising processor-executable instructions configured to implement one or more of the techniques presented herein. An exemplary computer-readable medium is illustrated in FIG. 6, wherein the embodiment 600 comprises a computer-readable medium 608 (e.g., a CD-R, DVD-R, flash drive, a platter of a hard disk drive, etc.), on which is encoded computer-readable data 606. This computer-readable data 606 in turn comprises a set of processor-executable computer instructions 604 configured to implement one or more of the principles set forth herein when executed by a processor. In some embodiments 600, the processor-executable computer instructions 604 are configured to implement a method 602, such as at least some of the aforementioned method(s) when executed by a processor. In some embodiments, the processor-executable computer instructions 604 are configured to implement a system, such as at least some of the one or more aforementioned system(s) when executed by a processor. Many such computer-readable media may be devised by those of ordinary skill in the art that are configured to operate in accordance with the techniques presented herein.

In some embodiments, a method is provided. The method includes: extending a probe of a probe card assembly to contact an electrical bump of an integrated circuit (IC) die, the IC die including a silicon photonic element thereon; extending an optical fiber of the probe card assembly to contact the silicon photonic element; and performing an electrooptical test on the IC die by a test head in electrical communication with the probe card assembly, including: transmitting a first test signal from the test head to the electrical bump via the probe, the first test signal being an electrical test signal; transmitting a second test signal via the probe card assembly to the silicon photonic element, the second test signal being an optical test signal.

In some embodiments, a method is provided. The method includes: transmitting a first optical test signal from a probe assembly to a first silicon photonic element of an integrated circuit (IC) die; transmitting a first electrical signal associated with the first optical test signal from the probe assembly to a first circuit structure of the IC die; generating a first optical signal by the first circuit structure based on the first optical test signal and the first electrical signal; and receiving the first optical signal by an optical receiver of the probe assembly.

In some embodiments, a system is provided. The system includes: a test head; and a probe card assembly in electrical communication with the test head. The probe card assembly includes: a probe card; and a jig assembly mounted to the probe card. The system includes: a first optical transmitter in electrical communication with the test head, the first optical transmitter being positioned in the probe card assembly; and a first optical fiber in optical communication with the first optical transmitter, the first optical fiber extending through the jig assembly.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” and/or the like is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method, comprising:
extending a probe of a probe card assembly to contact an electrical bump of an integrated circuit (IC) die, the IC die including a silicon photonic element thereon;
extending an optical fiber of the probe card assembly to contact the silicon photonic element; and
performing an electrooptical test on the IC die by a test head in electrical communication with the probe card assembly, including:
transmitting a first test signal from the test head to the electrical bump via the probe, the first test signal being an electrical test signal; and
transmitting a second test signal via the probe card assembly to the silicon photonic element, the second test signal being an optical test signal.

2. The method of claim 1, wherein transmitting the second test signal includes:
transmitting the optical test signal from the test head via an optical transmitter positioned in a probe card of the probe card assembly.

3. The method of claim 1, wherein transmitting the second test signal includes:
generating the optical test signal by an electric-to-optical modulator based on an electrical signal, the electric-to-optical modulator being positioned in a probe card of the probe card assembly; and
transmitting the optical test signal from the electric-to-optical modulator via an optical transmitter positioned in the probe card.

4. The method of claim 1, wherein transmitting the second test signal includes:
generating the optical test signal by an electric-to-optical modulator based on an electrical signal, the electric-to-optical modulator being positioned in a multilayer organic (MLO) substrate bonded to a probe card of the probe card assembly; and
transmitting the optical test signal from the electric-to-optical modulator via an optical transmitter positioned in the MLO substrate.

5. The method of claim 1, wherein transmitting the second test signal includes:
generating the optical test signal by an electric-to-optical modulator based on an electrical signal, the electric-to-optical modulator being positioned in a jig assembly mounted to a probe card of the probe card assembly; and
transmitting the optical test signal from the electric-to-optical modulator via an optical transmitter positioned in the jig assembly.

6. The method of claim 1, wherein transmitting the second test signal includes:
transmitting the optical test signal from the test head via a laser positioned in a probe card of the probe card assembly.

7. The method of claim 1, wherein transmitting the second test signal includes:
transmitting the optical test signal from the test head via a laser positioned in a multilayer organic (MLO) substrate bonded to a probe card of the probe card assembly.

8. The method of claim 1, wherein transmitting the second test signal includes:
transmitting the optical test signal from the test head via a laser positioned in a jig assembly mounted to a probe card of the probe card assembly.

9. A method comprising:
transmitting a first optical test signal from a probe assembly to a first silicon photonic element of an integrated circuit (IC) die;
transmitting a first electrical signal associated with the first optical test signal from the probe assembly to a first circuit structure of the IC die;
generating a first optical signal by the first circuit structure based on the first optical test signal and the first electrical signal; and
receiving the first optical signal by an optical receiver of the probe assembly.

10. The method of claim 9, further comprising:
generating a second optical signal associated with the first optical signal;
receiving the second optical signal by a third silicon photonic element;
generating a third electrical signal associated with the second optical signal by a second circuit structure of the IC die; and
receiving the third electrical signal by the probe assembly.

11. The method of claim 10, wherein:
transmitting the first optical test signal includes transmitting the first optical test signal via a first optical fiber;
receiving the first optical signal includes receiving the first optical signal via a second optical fiber; and
receiving the second optical signal includes receiving the second optical signal via a third optical fiber.

12. The method of claim 11, wherein:
transmitting the first optical test signal via the first optical fiber includes transmitting the first optical test signal via the first optical fiber that extends through a lower die of a jig assembly mounted to a probe card of the probe assembly.

13. The method of claim 12, further comprising:
determining optical power associated with alignment of the first optical fiber with the first silicon photonic element; and
increasing the optical power by a micro-electromechanical system (MEMS) positioned in the lower die of the jig assembly.

14. The method of claim 11, wherein:
transmitting the first optical test signal via the first optical fiber includes transmitting the first optical test signal via the first optical fiber that extends through an upper die of a jig assembly that is offset from a lower die of the jig assembly by a spacer.

15. The method of claim 14, wherein:
transmitting the first optical test signal via the first optical fiber includes transmitting the first optical test signal via the first optical fiber that extends through a jig of the jig assembly to which the spacer, the upper die and the lower die are mounted.

16. A system, comprising:
a test head;
a probe card assembly in electrical communication with the test head, the probe card assembly including:
a probe card; and
a jig assembly mounted to the probe card;
a first optical transmitter in electrical communication with the test head, the first optical transmitter being positioned in the probe card assembly; and
a first optical fiber in optical communication with the first optical transmitter, the first optical fiber extending through the jig assembly.

17. The system of claim 16, wherein the first optical transmitter is positioned in the probe card.

18. The system of claim 16, further comprising:
an actuator positioned in the jig assembly, the actuator, in operation, selecting position of the first optical fiber.

19. The system of claim 18, wherein the jig assembly includes:
an upper die, the first optical transmitter being positioned in the upper die; and
a lower die offset from the upper die, the actuator being positioned in the lower die.

20. The system of claim 18, wherein the jig assembly includes:
a lower die, the actuator being positioned in the lower die;
an upper die positioned between the lower die and the probe card; and
a multilayer organic (MLO) substrate positioned between the upper die and the probe card, the first optical transmitter being positioned in the MLO substrate.
